(19) United States
(12) Patent Application Publication
(10) Pub. No.: US 2025/0336443 A1
(43) Pub. Date: Oct. 30, 2025

(54) SEMICONDUCTOR APPARATUS AND METHOD FOR OPERATING THE SEMICONDUCTOR APPARATUS

(71) Applicant: SK hynix Inc., Icheon-si Gyeonggi-do (KR)

(72) Inventor: Kyung Yun JEONG, Icheon-si Gyeonggi-do (KR)

(73) Assignee: SK hynix Inc., Icheon-si Gyeonggi-do (KR)

(21) Appl. No.: 18/809,001

(22) Filed: Aug. 19, 2024

(30) Foreign Application Priority Data
Apr. 29, 2024 (KR) 10-2024-0056552

(51) Int. Cl. G11C 16/10; G11C 16/04; G11C 16/08; G11C 16/24; G11C 16/34

(52) U.S. Cl. CPC G11C 16/10; G11C 16/0483; G11C 16/08; G11C 16/24; G11C 16/3459

(57) ABSTRACT

A method for operating a semiconductor apparatus includes receiving a program command, applying a program pulse to a memory cell, sensing a threshold voltage of the memory cell, determining whether a program is completed according to a result of the sensing of the threshold voltage of the memory cell and increasing a voltage level of a bit line connected to the memory cell by a voltage level corresponding to a level of the threshold voltage of the memory cell according to a determination result in the determining of whether the program has completed.

### CROSS-REFERENCE TO RELATED APPLICATION

The present application claims priority under 35 U.S.C. § 119(a) to Korean Patent Application No. 10-2024-0056552 filed in the Korean Intellectual Property Office, on Apr. 29, 2024, which application is incorporated herein by reference in its entirety.

### BACKGROUND

### 1. Technical Field

Embodiments of the present disclosure generally relate to an integrated circuit technology, and more particularly, to a semiconductor apparatus related to programming and a method for operating the semiconductor apparatus.

### 2. Related Art

Recently, with the miniaturization, low power consumption, high performance, diversification, and the like of electronic devices, there is a demand for semiconductor apparatuses capable of storing information in various electronic devices such as computers and portable communication devices. The semiconductor apparatuses may be roughly classified into volatile memory apparatuses and nonvolatile memory apparatuses. The volatile memory apparatus has a high data processing speed, but has a disadvantage in that power needs to be continuously supplied in order to retain stored data, and the nonvolatile memory apparatus does not need to be continuously supplied with power in order to retain stored data, but has a disadvantage in that a data processing speed is low.

Accordingly, research is continuing to improve the data processing speed of the nonvolatile memory apparatus, that is, the operation speed thereof, and to improve the threshold voltage distribution of a memory cell.

### SUMMARY

In an embodiment, a method for operating a semiconductor apparatus may include: receiving a program command, applying a program pulse to a memory cell, sensing a threshold voltage of the memory cell, determining whether a program is completed according to a result of the sensing of the threshold voltage of the memory cell and increasing a voltage level of a bit line connected to the memory cell by a voltage level corresponding to a level of the threshold voltage of the memory cell according to a determination result in the determining of whether the program has completed.

In another embodiment, a semiconductor apparatus may include: a cell string connected between a source line and a bit line and comprising at least one memory cell, a line driving circuit that drives a word line connected to the memory cell, a page buffer connected to the bit line and a control circuit configured to control the line driving circuit to provide a program pulse to the word line during a program operation, and control the page buffer through the bit line to determine whether the memory cell has been programmed, wherein, before the program pulse with an increased level after the bit line is discharged is provided to the word line, the page buffer increases a voltage level of the bit line discharged by a voltage level corresponding to a threshold voltage level of the memory cell under the control of the control circuit.

### BRIEF DESCRIPTION OF THE DRAWINGS

FIG. 1 is a diagram illustrating the configuration of a semiconductor apparatus in accordance with an embodiment of the present disclosure.

FIG. 2 is a diagram illustrating the configuration of a page buffer included in the semiconductor apparatus in accordance with an embodiment of the present disclosure.

FIG. 3 is a timing diagram for explaining the operation of the page buffer included in the semiconductor apparatus in accordance with an embodiment of the present disclosure.

FIG. 4 is a diagram for explaining a program operation of the semiconductor apparatus in accordance with an embodiment of the present disclosure.

FIG. 5 is a graph for explaining a change in the voltage level of a sensing node according to the program operation of the semiconductor apparatus in accordance with an embodiment of the present disclosure.

FIG. 6 is a flowchart for explaining the operation of the semiconductor apparatus in accordance with an embodiment of the present disclosure.

### DETAILED DESCRIPTION

Various embodiments are directed to a semiconductor apparatus that supports an improved incremental step pulse programming (ISPP) operation and a method for operating the semiconductor apparatus.

In an embodiment, the threshold voltage distribution of a cell can be improved.

Hereafter, embodiments in accordance with the technical spirit of the present disclosure will be described with reference to the accompanying drawings.

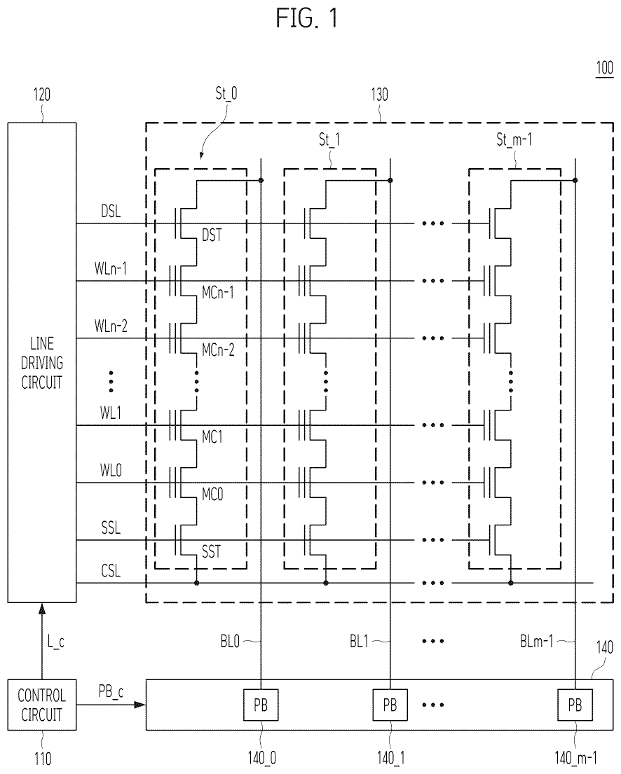

FIG. 1 is a diagram illustrating the configuration of a semiconductor apparatus 100 in accordance with an embodiment of the present disclosure.

Referring to FIG. 1, the semiconductor apparatus 100 in accordance with an embodiment of the present disclosure includes a control circuit 110, a line driving circuit 120, a cell string group 130, and a page buffer group 140.

In an embodiment, the control circuit 110 controls the line driving circuit 120 and the page buffer group 140 to program data into the cell string group 130 or to erase data programmed into the cell string group 130. In such a case, the control circuit 110 provides a line driving control signal L_c to the line driving circuit 120. In an embodiment, the control circuit 110 provides a page buffer control signal PB_c to the page buffer group 140.

In an embodiment, the line driving circuit 120 drives a drain select line DSL, word lines WL0 to WLn−1, and a source select line SSL to internal voltage levels, respectively, on the basis of the line driving control signal L_c. During a program operation, the line driving circuit 120 applies a program voltage being one of the internal voltages to at least one of the word lines WL0 to WLn−1 under the control of the control circuit 110. In such a case, the level of the program voltage provided by the line driving circuit 120 to the word lines WL0 to WLn−1 and the application time of the program voltage are controlled on the basis of the line driving control signal L_c. In such a case, the level of the program voltage provided to the word lines WL0 to WLn−1 during the program operation and the application time of the program voltage are referred to as a program pulse, the voltage level of the program pulse corresponds to the level of the program voltage, and the width of the program pulse corresponds to the application time of the program voltage.

In an embodiment, the cell string group 130 includes a plurality of cell strings St_0 to St_m−1. The cell string St_0 is connected between a bit line BL0 and a source line CSL, the cell string St_1 is connected between a bit line BL1 and the source line CSL, and the cell string St_m−1 is connected between a bit line BLm−1 and the source line CSL. Each of the plurality of cell strings St_0 to St_m−1 includes a drain select transistor DST, a plurality of cell transistors MC0 to MCn−1, and a source select transistor SST. In such a case, because the configurations of the plurality of cell strings St_0 to St_m−1 are the same except for only the names of input signals or connected lines, the configuration of the cell string St_0 among the plurality of cell strings St_0 to St_m−1 will be representatively described.

In an embodiment, the cell string St_0 includes the drain select transistor DST, the plurality of cell transistors MC0 to MCn−1, and the source select transistor SST connected in series between the bit line BL0 and the source line CSL.

In an embodiment, the drain select transistor DST includes a gate to which the drain select line DSL is connected, and a drain and a source to which the bit line BL0 and the cell transistor MCn−1 are connected, respectively.

In an embodiment, the plurality of cell transistors MC0 to MCn−1 are connected in series between the drain select transistor DST and the source select transistor SST, and the plurality of word lines WL0 to WLn−1 are connected to the gates of the cell transistors MC0 to MCn−1, respectively. In such a case, each of the plurality of cell transistors MC0 to MCn−1 serves as a memory cell in which data is programmed and erased. Hereinafter, each of the plurality of cell transistors MC0 to MC_n−1 is referred to as a memory cell.

In an embodiment, the source select transistor SST includes a gate to which the source select line SSL is connected, and a drain and a source to which the cell transistor MC0 and the source line CSL are connected, respectively.

In an embodiment, the page buffer group 140 includes a plurality of page buffers (PBs) 140_0 to 140_m−1. The page buffers 140_0 to 140_m−1 are connected to the plurality of bit lines BL0 to BLm−1, respectively. The plurality of page buffers 140_0 to 140_m−1 sense threshold voltages of the memory cells MC0 to MCm−1 through the connected bit lines BL0 to BLm−1, respectively. The page buffer group 140 provides the control circuit 110 with a threshold voltage sensing value of a memory cell sensed by at least one of the plurality of page buffers 140_0 to 140_m−1.

In an embodiment, the semiconductor apparatus 100 configured in this way repeatedly provides a program pulse to at least one of the plurality of word lines WL0 to WLn−1 to program at least one of the plurality of memory cells MC0 to MCn−1. In such a case, with an increase in the number of times the program pulse is provided, a program pulse with a higher voltage level is provided to a word line.

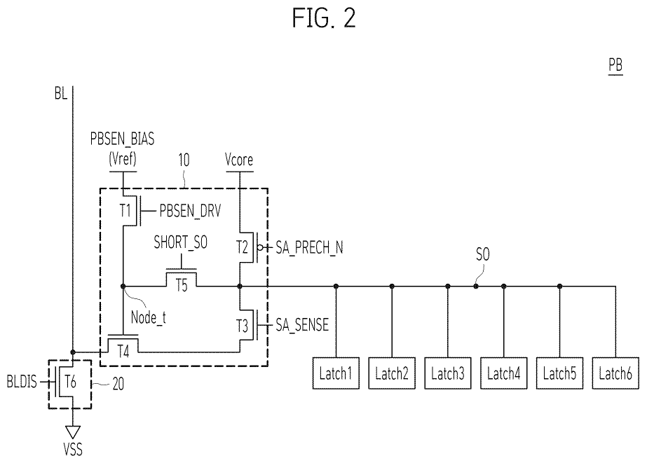

FIG. 2 is a diagram illustrating the configuration of a page buffer included in the semiconductor apparatus in accordance with an embodiment of the present disclosure. In such a case, the page buffer PB illustrated in FIG. 2 shows the configuration of each of the plurality of page buffers 140_0 to 140_m−1 illustrated in FIG. 1 as an embodiment.

Referring to FIG. 2, the page buffer PB includes a connection circuit 10, a bit line discharge circuit 20, and a plurality of latches Latch1 to Latch6.

In an embodiment, the connection circuit 10 is configured to connect and disconnect a bit line BL and a sensing node SO. For example, the connection circuit 10 connects the bit line BL and the sensing node SO during a read operation or a program verify operation, or after the program verify operation is performed and the bit line BL is discharged. More specifically, when a voltage corresponding to a threshold voltage of a memory cell MC selected during the read operation is generated on the bit line BL, the connection circuit 10 connects the bit line BL and the sensing node SO so that the voltage of the bit line BL is transferred to the sensing node SO. During the program verify operation, as with the read operation, when the voltage corresponding to the threshold voltage of the selected memory cell MC is generated on the bit line BL, the connection circuit 10 connects the bit line BL and the sensing node SO so that the voltage of the bit line BL is transferred to the sensing node SO. As described above, when the program verify operation is performed, the voltage of the bit line BL is transferred to the sensing node SO, and the voltage level of the sensing node SO increases. Subsequently, when the bit line BL is discharged and a ground voltage level of the bit line BL is reached, the connection circuit 10 connects the bit line BL and the sensing node SO so that the voltage level of the sensing node SO is transferred to the bit line BL.

In an embodiment, the connection circuit 10 is implemented with a plurality of transistors T1 to T5. In an embodiment, the connection circuit 10 includes first to fifth transistors T1 to T5. In such a case, signals input to the connection circuit 10 are signals included in the page buffer control signal PB_c illustrated in FIG. 1. In an embodiment, the page buffer control signal PB_c includes a driving signal PBSEN_DRV, a precharge signal SA_PRECH_N, a sensing signal SA_SENSE, and a connection signal SHORT_SO.

In an embodiment, the first transistor T1 is configured to transfer a sensing bias voltage PBSEN_BIAS to a transfer node Node_t on the basis of the driving signal PBSEN_DRV. In an embodiment, the first transistor T1 includes a gate to which the driving signal PBSEN_DRV is input, a drain to which the sensing bias voltage PBSEN_BIAS is applied, and a source to which the transfer node Node_t is connected. The first transistor T1 configured in this way transfers the sensing bias voltage PBSEN_BIAS to the transfer node Node_t when the driving signal PBSEN_DRV is enabled. The sensing bias voltage PBSEN_BIAS is a reference voltage Vref.

In an embodiment, the second transistor T2 is configured to transfer a core voltage Vcore to the sensing node SO on the basis of the precharge signal SA_PRECH_N. In an embodiment, the second transistor T2 includes a gate to which the precharge signal SA_PRECH_N is input, a source to which the core voltage Vcore is applied, and a drain to which the sensing node SO is connected. The second transistor T2 configured in this way transfers the core voltage Vcore to the sensing node SO when the precharge signal SA_PRECH_N is enabled.

In an embodiment, the third transistor T3 is configured to connect the sensing node SO to a drain of the fourth transistor T4 on the basis of the sensing signal SA_SENSE. In an embodiment, the third transistor T3 includes a gate to which the sensing signal SA_SENSE is input, a drain to which the sensing node SO is connected, and a source to which the drain of the fourth transistor T4 is connected. The third transistor T3 configured in this way connects the sensing node SO and the drain of the fourth transistor T4 when the sensing signal SA_SENSE is enabled.

In an embodiment, the fourth transistor T4 is configured to connect the source of the third transistor T3 to the bit line BL on the basis of a voltage level of the transfer node Node_t. In an embodiment, the fourth transistor T4 includes a gate to which the transfer node Node_t is connected, the drain to which the source of the third transistor T3 is connected, and a source to which the bit line BL is connected. The fourth transistor T4 configured in this way connects the source of the third transistor T3 and the bit line BL when the voltage level of the transfer node Node_t is higher than a preset voltage level. The word “preset” as used herein with respect to a parameter, such as a preset voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

In an embodiment, the fifth transistor T5 is configured to connect the sensing node SO and the transfer node Node_t on the basis of the connection signal SHORT_SO. In an embodiment, the fifth transistor T5 includes a gate to which the connection signal SHORT_SO is input, and a drain and a source to which the sensing node SO and the transfer node Node_t are connected, respectively. The fifth transistor T5 configured in this way connects the sensing node SO and the transfer node Node_t when the connection signal SHORT_SO is enabled.

In an embodiment, the connection circuit 10 includes the first to fifth transistors T1 to T5, and the first to fifth transistors T1 to T5 are all transistors of the same type. In an embodiment, among the first to fifth transistors T1 to T5 constituting the connection circuit 10, at least one transistor is a different type of transistor from the remaining transistors. In an embodiment, the second transistor T2 constituting the connection circuit 10 is a different type of transistor from the remaining transistors T1, T3, T4, and T5. For example, the second transistor T2 is a P-type transistor, and the first transistor T1, third transistor T3, fourth transistor T4, and fifth transistor T5 are N-type transistors.

In an embodiment, the bit line discharge circuit 20 discharges the bit line BL on the basis of a discharge signal BLDIS. In an embodiment, the bit line discharge circuit 20 includes one transistor. The bit line discharge circuit 20 includes a sixth transistor T6.

In an embodiment, the sixth transistor T6 is configured to discharge the bit line BL on the basis of the discharge signal BLDIS. In an embodiment, the sixth transistor 20 includes a gate to which the discharge signal BLDIS is input, a drain to which the bit line BL is connected, and a source to which a ground terminal VSS is connected. In such a case, a voltage level of the ground terminal VSS is a ground voltage (ground). When the discharge signal BLDIS is enabled, the bit line discharge circuit 20 configured in this way, that is, the sixth transistor T6 connects the bit line BL and the ground terminal VSS to discharge the bit line BL. In such a case, the voltage level of the discharged bit line BL is the level of the ground voltage VSS.

In an embodiment, the plurality of latches Latch1 to Latch6 are configured to be commonly connected to the sensing node SO. In an embodiment, the plurality of latches Latch1 to Latch6 include first to sixth latches Latch1 to Latch6 commonly connected to the sensing node SO. Each of the first to sixth latches Latch1 to Latch6 configured in this way is configured to store the voltage level of the sensing node SO on the basis of the page buffer control signal PB_c (not illustrated), or to transfer a voltage level corresponding to the stored level to the sensing node SO. In such a case, when the voltage level of the sensing node SO is equal to or higher than a preset voltage level, each of the first to sixth latches Latch1 to Latch6 stores the voltage level of the sensing node SO to a first level. When the voltage level of the sensing node SO is less than the preset voltage level, each of the first to sixth latches Latch1 to Latch6 stores the voltage level of the sensing node SO to a second level. The first level and the second level are different digital logic levels.

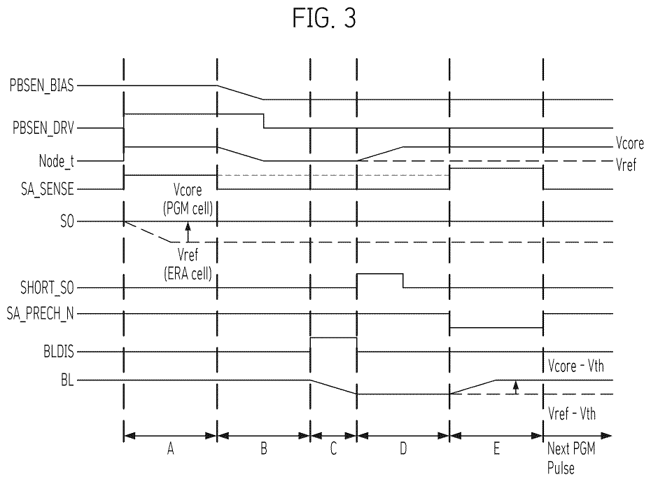

FIG. 3 is a timing diagram for explaining the operation of the page buffer included in the semiconductor apparatus in accordance with an embodiment of the present disclosure. Referring to FIG. 3, the operation of the page buffer configured as illustrated in FIG. 2 will be described as follows.

Referring to FIG. 3, the operation of the page buffer PB included in the semiconductor apparatus in accordance with the embodiment of the present disclosure includes a sensing operation period A, a transfer node precharge operation period B, a bit line discharge operation period C, a transfer node voltage increase period D, and a sensing node voltage transfer period E.

In an embodiment, the sensing operation period A is a period of sensing the threshold voltage of a memory cell being programmed. In such a case, the sensing operation period A includes a period of turning on the first transistor T1 by enabling the driving signal PBSEN_DRV and turning on the third transistor T3 by enabling the sensing signal SA_SENSE. The sensing operation period A further includes a period in which the first transistor T1 is turned on and the sensing bias voltage PBSEN_BIAS being the reference voltage Vref level is transferred to the transfer node Node_t, so that the fourth transistor T4 is turned on. Accordingly, the sensing operation period A is a period in which the third transistor T3 and the fourth transistor T4 are turned on and the bit line BL is connected to the sensing node SO.

In general, the threshold voltage level of a memory cell being programmed, that is, a memory cell, to which a program pulse has been applied, increases. When the threshold voltage level of the memory cell increases, the voltage level of the bit line BL changes during the sensing operation. In such a case, as illustrated in FIG. 3, as a verify operation for the program operation, a sensing operation is performed during the sensing operation period A. During the sensing operation period A, that is, while the third and fourth transistors T3 and T4 are turned on and the bit line BL and the sensing node SO are connected, the voltage level of the bit line BL is transferred to the sensing node SO. Accordingly, in the case of a memory cell ERA cell in an erase state, the voltage level of the sensing node SO in the sensing operation period A is the level of the sensing bias voltage PBSEN_BIAS, that is, the level of the reference voltage Vref. In the case of a memory cell PGM cell in which a program has been completed, the voltage level of the sensing node SO in the sensing operation period A is the level of the core voltage Vcore. When the semiconductor apparatus in accordance with an embodiment of the present disclosure supports an incremental step pulse program (ISPP), the voltage level of the sensing node SO in the sensing operation period A sequentially increases from the level of the reference voltage Vref to the level of the core voltage Vcore each time a program pulse is provided to a memory cell. That is, when a program operation is performed from a memory cell in an erase state to a memory cell in a program state, the voltage level of the sensing node SO gradually increases or increases. In such a situation, when the voltage level of the sensing node SO is higher than a preset voltage level, one of the first to sixth latches Latch1 to Latch6 stores a first level, and when the voltage level of the sensing node SO is lower than the preset voltage level, one of the first to sixth latches Latch1 to Latch6 stores a second level. In an embodiment, when the first level is stored in the latch, it is determined that the program operation for the memory cell has been completed, and when the second level is stored in the latch, it is determined that the program operation for the memory cell has not been completed.

As a consequence, the sensing operation period A in accordance with the embodiment of the present disclosure illustrated in FIG. 3 is a period of connecting the bit line BL and the sensing node SO by turning on the third and fourth transistors T3 and T4 of the connection circuit 10 during the verify operation for the program.

In an embodiment, the transfer node precharge operation period B is a period of disconnecting the bit line BL and the sensing node SO connected in the sensing operation period A. In an embodiment, the transfer node precharge operation period B includes a period of turning off the fourth transistor T4 by precharging the transfer node Node_t and turning off the third transistor T3 by disabling the sensing signal SA_SENSE. In such a case, in the transfer node precharge operation period B, the level of the sensing bias voltage PBSEN_BIAS is lowered in a state in which the driving signal PBSEN_DRV is enabled, that is, the first transistor T1 is turned on, so that the transfer node Node_t is precharged.

In an embodiment, the bit line discharge operation period C includes an operation period of lowering the voltage level of the bit line BL having a voltage level that has increased in the sensing operation period A, that is, an operation period of sensing a memory cell being programmed. In an embodiment, the bit line discharge operation period C includes a period of turning on the sixth transistor T6 by enabling the discharge signal BLDIS. In such a case, in the bit line discharge operation period C, a bit line discharge operation is performed to lower the voltage of the bit line BL during the enable period of the discharge signal BLDIS.

In an embodiment, the transfer node voltage increase period D includes an operation period of connecting the transfer node Node_t and the sensing node SO by enabling the connection signal SHORT_SO after the bit line BL is discharged. In such a case, the voltage of the sensing node SO having a level that has increased according to the number of times the program pulse is provided in the sensing operation period A is transferred to the transfer node Node_t in the transfer node voltage increase period D. Accordingly, in the transfer node voltage increase period D, the fourth transistor T4 may also be turned on due to the transfer node Node_t having a level that has increased according to the number of times the program pulse is provided.

In an embodiment, the sensing node voltage transfer period E includes a period in which the voltage of the sensing node SO having a level that has increased according to the number of times, by which the program pulse is provided, is transferred to the bit line BL. In an embodiment, the sensing node voltage transfer period E includes an operation period of turning on the third transistor T3 by enabling the sensing signal SA_SENSE. Accordingly, the sensing node SO and the bit line BL are connected by the fourth transistor T4 turned on in the transfer node voltage increase period D and the third transistor T3 turned on in the sensing node voltage transfer period E. Therefore, the sensing node voltage transfer period E is a period in which a voltage is transferred from the sensing node SO, having a voltage level that has increased according to the number of times the program pulse is provided, to the discharged bit line BL. As a consequence, the sensing node voltage transfer period E is a period in which the voltage of the sensing node SO is transferred to the discharged bit line BL and the voltage level of the bit line BL increases. The sensing signal SA_SENSE enabled in the sensing node voltage transfer period E is at a higher level than the level of the sensing signal SA_SENSE enabled in the sensing operation period A. Moreover, in the sensing node voltage transfer period E, the precharge signal SA_PRECH_N is also enabled to precharge the sensing node SO to the level of the core voltage Vcore when a program has been completed in the memory cell.

For example, when the sensing node voltage transfer period E ends, a next program pulse Next PGM pulse is provided to the memory cell.

As described above, the semiconductor apparatus in accordance with an embodiment of the present disclosure increases the voltage level of the bit line BL before a program pulse is provided, thereby reducing the threshold voltage shift width of a memory cell being programmed when a next program pulse is provided and improving the threshold voltage distribution of the memory cell.

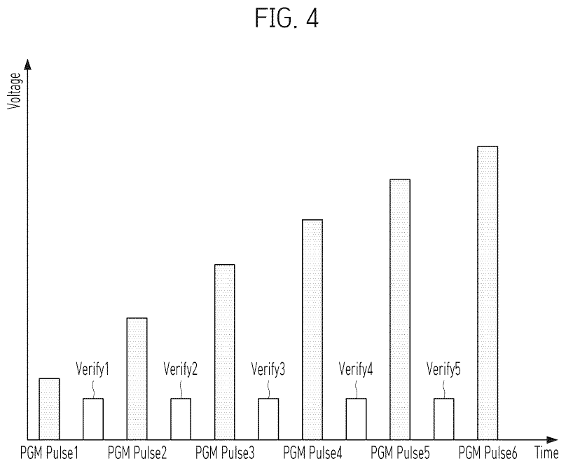

FIG. 4 is a diagram for explaining a program operation of the semiconductor apparatus in accordance with an embodiment of the present disclosure.

Referring to FIG. 4, the program operation of the semiconductor apparatus in accordance with an embodiment of the present disclosure supports an incremental step pulse program (ISPP) operation.

In an embodiment, the incremental step pulse program (ISPP) operation is a program operation in which program pulses PGM Pulse1 to PGM Pulse6, each of which the voltage level increases until a program for a memory cell is completed, are sequentially provided to the memory cell. In such a case, whenever each of the program pulses PGM Pulse1 to PGM Pulse6 is provided to the memory cell, verify operations Verify1 to Verify5 for the provided program pulses are performed. More specifically, after a first program pulse PGM Pulse1 is provided to the memory cell, a first verify operation Verify1 is performed, and after a second program pulse PGM Pulse2 is provided to the memory cell, a second verify operation Verify2 is performed. After a third program pulse PGM Pulse3 is provided to the memory cell, a third verify operation Verify3 is performed, and after a fourth program pulse PGM Pulse4 is provided to the memory cell, a fourth verify operation Verify4 is performed. After a fifth program pulse PGM Pulse5 is provided to the memory cell, a fifth verify operation Verify5 is performed, and after a sixth program pulse PGM Pulse6 is provided to the memory cell, a sixth verify operation Verify6 is performed.

When the semiconductor apparatus in accordance with an embodiment of the present disclosure performs the ISPP operation, the page buffer in accordance with an embodiment of the present disclosure performs the operation of the page buffer illustrated in FIG. 3 during each verify operation.

Accordingly, as described above, the semiconductor apparatus in accordance with an embodiment of the present disclosure transfers, to the bit line BL, the voltage of the sensing node SO having a voltage level increasing each time a program pulse is provided to a memory cell, thereby reducing the shift width of the memory cell when a next program pulse is provided and improving the threshold voltage distribution of the memory cell programmed.

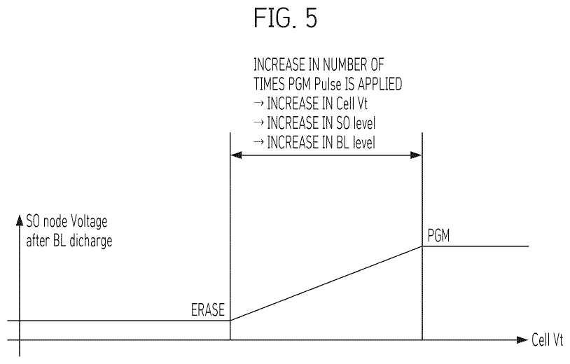

FIG. 5 is a graph for explaining a change in the voltage level of a sensing node according to the program operation of the semiconductor apparatus in accordance with an embodiment of the present disclosure. FIG. 5 illustrates a change in the voltage level of the sensing node after a bit line is discharged. In such a case, the program operation is a program operation of supporting ISPP.

In the graph in FIG. 5, a vertical axis denotes a change in the voltage level of the sensing node SO after the bit line BL is discharged, and a horizontal axis denotes a change in a threshold voltage Cell Vt of the memory cell according to the program operation of supporting the ISPP.

Referring to FIGS. 3 and 5, first, the voltage level of the sensing node SO for a memory cell in an erase state ERASE is the reference voltage Vref. With an increase in the number of times a program pulse PGM Pulse is provided to the memory cell in the erase state ERASE, the voltage level of the sensing node SO, which is the level of the reference voltage Vref, increases. In such a case, the voltage level of the sensing node SO for the memory cell in the program state PGM is the level of the core voltage Vcore, that is, the voltage level of the sensing node SO when the program has been completed is the level of the core voltage Vcore.

In an embodiment, the operation of the page buffer during the program operation of the semiconductor apparatus in accordance with an embodiment of the present disclosure also increases the voltage level of the sensing node SO as the number of times, by which a program pulse is provided, increases, that is, as the threshold voltage of a memory cell increases closer to a program target level. As the voltage level of the sensing node SO increases, the voltage level of the bit line BL increases. Subsequently, in an embodiment, when the next program pulse Next PGM Pulse is provided, the threshold voltage shift width of the memory cell is reduced due to the bit line BL with an increased voltage level, and thus, the threshold voltage distribution of the memory cell is improved.

As a consequence, the semiconductor apparatus in accordance with an embodiment of the present disclosure is configured to increase the voltage level of a bit line connected to a memory cell being programmed according to the number of times a program pulse is provided, and operates to improve the threshold voltage distribution of the memory cell for the program operation.

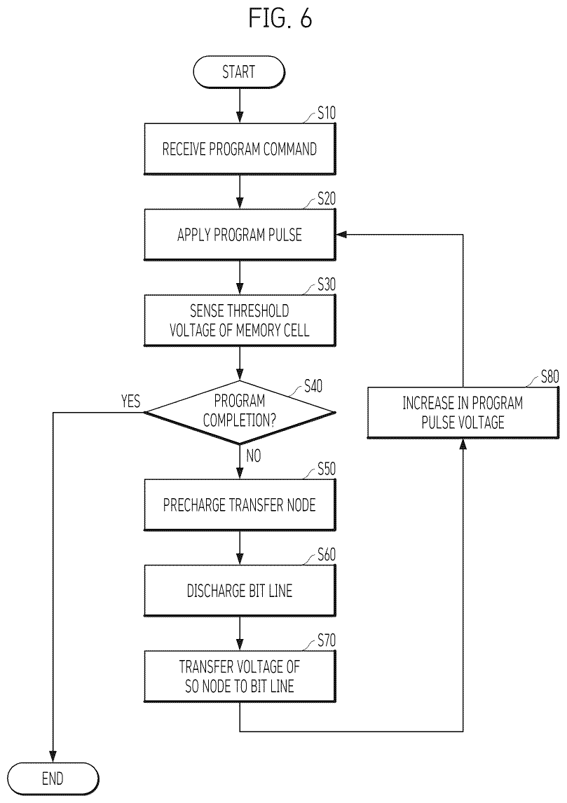

FIG. 6 is a flowchart for explaining the operation of the semiconductor apparatus in accordance with an embodiment of the present disclosure.

Referring to FIG. 6, a method for operating the semiconductor apparatus in accordance with an embodiment of the present disclosure includes a program command receiving process S10, a program pulse applying process S20, a memory cell threshold voltage sensing process S30, a program completion determination process S40, a transfer node precharge process S50, a bit line discharge process S60, a voltage transfer process S70, and a program pulse voltage increase process S80.

In an embodiment, the program command receiving process S10 includes a process of confirming that a program command is received by the semiconductor apparatus. When the reception of the program command is confirmed in the program command receiving process S10, the program operation of the semiconductor apparatus is started.

In an embodiment, the program pulse applying process S20 includes a process of applying a program pulse to a word line connected to a target memory cell of the program operation.

In an embodiment, the memory cell threshold voltage sensing process S30 is a process of sensing the threshold voltage of the target memory cell to which the program pulse has been applied, and is a process performed in the page buffer PB through the bit line BL connected to the target memory cell. In such a case, the memory cell threshold voltage sensing process S30 is an operation method corresponding to the sensing operation period A of FIG. 3.

In an embodiment, the program completion determination process S40 includes a process of determining a result of sensing the threshold voltage of the target memory cell in the memory cell threshold voltage sensing process S30.

When the result of sensing the threshold voltage of the target memory cell is determined to be a program completion (Yes) in the program completion determination process S40, the method for operating a semiconductor apparatus in accordance with an embodiment of the present disclosure ends.

However, when the result of sensing the threshold voltage of the target memory cell is not determined to be the program completion (No) in the program completion determination process S40, the transfer node precharge process S50 is performed.

In an embodiment, the transfer node precharge process S50 is a process of precharging the transfer node Node_t inside the page buffer PB illustrated in FIG. 2, and is an operation method corresponding to the transfer node precharge operation period B illustrated in FIG. 3. The transfer node precharge process S50 turns off the fourth transistor T4 by precharging the transfer node Node_t, thereby disconnecting the sensing node SO and the bit line BL connected in the memory cell threshold voltage sensing process S30.

In an embodiment, the bit line discharge process S60 includes a process of discharging the bit line BL disconnected from the sensing node SO in the transfer node precharge process S50. The bit line discharge process S60 is an operation method corresponding to the bit line discharge operation period C illustrated in FIG. 3. Accordingly, the bit line discharge process S60 is an operation process of lowering the voltage level of the bit line generated by the threshold voltage of the memory cell to which the program pulse is provided in the memory cell threshold voltage sensing process S30.

In an embodiment, the voltage transfer process S70 includes a process of transferring, to the bit line BL, the voltage of the sensing node SO having a level that has increased in the memory cell threshold voltage sensing process S30. In such a case, the voltage transfer process S70 is an operation method corresponding to the transfer node voltage increase period D and the sensing node voltage transfer period E illustrated in FIG. 3. The voltage transfer process S70 is a process of connecting the sensing node SO and the bit line BL by turning on the fourth transistor T4 in the transfer node voltage increase period D and turning on the third transistor T3 in the sensing node voltage transfer period E. In such a case, when the sensing node SO and the bit line BL are connected in the voltage transfer process S70, the voltage of the sensing node SO having a level that has increased in the memory cell threshold voltage sensing process S30 is transferred to the bit line BL.

In an embodiment, the program pulse voltage increase process S80 includes a process of increasing the voltage level of the program pulse. As illustrated in FIG. 4, the program pulse voltage increase process S80 is a process of gradually increasing the voltage level of the program pulse until the program is completed for the target memory cell.

After the program pulse voltage increase process S80, the program pulse applying process S20 is performed.

As described above, the method for operating a semiconductor apparatus in accordance with an embodiment of the present disclosure increases the voltage level of a sensing node each time a program pulse is applied and transfers the sensing node voltage with an increased voltage level to a bit line before a next program pulse is applied, thereby reducing the shift width of a threshold voltage of a memory cell and improving a threshold voltage distribution of the memory cell.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A method for operating a semiconductor apparatus, comprising:
receiving a program command;
applying a program pulse to a memory cell;
sensing a threshold voltage of the memory cell;
determining whether a program is completed according to a result of the sensing of the threshold voltage of the memory cell; and
increasing a voltage level of a bit line connected to the memory cell by a voltage level corresponding to a level of the threshold voltage of the memory cell according to a determination result in the determining of whether the program has completed.

2. The method for operating a semiconductor apparatus of claim 1, wherein, in the increasing of the voltage level of the bit line, the voltage level of the bit line discharged as a program operation is performed from a memory cell in an erase state to a memory cell in a program state is increased.

3. The method for operating a semiconductor apparatus of claim 1, wherein, in the increasing of the voltage level of the bit line, a voltage of a sensing node with a level increased in the sensing of the threshold voltage of the memory cell is transferred to the discharged bit line.

4. The method for operating a semiconductor apparatus of claim 3, further comprising:
increasing a voltage level of the program pulse after the increasing of the voltage level of the bit line,
wherein the applying of the program pulse to the memory cell is performed again after the increasing of the voltage level of the program pulse.

5. The method for operating a semiconductor apparatus of claim 4, wherein the increasing of the voltage level of the bit line comprises:
disconnecting the sensing node and the bit line connected in the sensing of the threshold voltage of the memory cell;
discharging the bit line; and
connecting the discharged bit line and the sensing node.

6. The method for operating a semiconductor apparatus of claim 1, wherein the sensing of the threshold voltage of the memory cell is performed when a sensing node and the bit line are connected, a plurality of latches included in a page buffer being commonly connected to the sensing node.

7. The method for operating a semiconductor apparatus of claim 6, wherein, in the determining of whether the program has completed, whether the memory cell has been programmed is determined on the basis of a voltage level of the sensing node when the voltage level of the bit line is transferred to the sensing node.

8. The method for operating a semiconductor apparatus of claim 7, wherein the increasing of the voltage level of the bit line is performed when it is determined in the determining of whether the program has completed that the memory cell has not been programmed.

9. A semiconductor apparatus comprising:
a cell string connected between a source line and a bit line and comprising at least one memory cell;
a line driving circuit that drives a word line connected to the memory cell;
a page buffer connected to the bit line; and
a control circuit configured to control the line driving circuit to provide a program pulse to the word line during a program operation, and control the page buffer through the bit line to determine whether the memory cell has been programmed,
wherein, before the program pulse with an increased level after the bit line is discharged is provided to the word line, the page buffer increases a voltage level of the bit line discharged by a voltage level corresponding to a threshold voltage level of the memory cell under the control of the control circuit.

10. The semiconductor apparatus of claim 9, wherein the page buffer comprises:
a plurality of latches commonly connected to a sensing node;
a connection circuit configured to connect and disconnect the bit line and the sensing node under the control of the control circuit; and
a bit line discharge circuit configured to discharge the bit line under the control of the control circuit.

11. The semiconductor apparatus of claim 8, wherein the connection circuit connects the bit line and the sensing node during a verify operation for determining whether the memory cell has been programmed,
disconnects the bit line and the sensing node when the bit line is discharged, and
connects the bit line and the sensing node before the program pulse with an increased level is provided to the word line.

12. The semiconductor apparatus of claim 11, wherein the connection circuit comprises:
a first transistor configured to transfer a sensing bias voltage to a transfer node on the basis of a driving signal;
a second transistor configured to connect the transfer node and the sensing node on the basis of a connection signal;
a third transistor configured to connect the bit line and a fourth transistor based on a voltage level of the transfer node; and
the fourth transistor configured to connect the sensing node and the third transistor on the basis of a sensing signal.

13. The semiconductor apparatus of claim 12, wherein the driving signal, the connection signal, and the sensing signal are provided from the control circuit.

14. The semiconductor apparatus of claim 12, wherein the connection circuit further comprises:
a fifth transistor configured to transfer a core voltage to the sensing node based on a precharge signal.

15. The semiconductor apparatus of claim 14, wherein the control circuit is configured to connect the bit line and the sensing node by turning on the first transistor, the third transistor, and the fourth transistor by enabling the driving signal and the sensing signal during the verify operation.

16. The semiconductor apparatus of claim 14, wherein the control circuit is configured to disconnect the bit line from the sensing node by turning off the first transistor, the third transistor, and the fourth transistor by disabling the driving signal and the sensing signal when the bit line is discharged.

17. The semiconductor apparatus of claim 14, wherein, when the voltage level of the bit line discharged by the voltage level corresponding to the threshold voltage level of the memory cell is increased before the program pulse with an increased level after the bit line is discharged is provided to the word line, the control circuit is configured to connect the bit line and the sensing node by turning on the third transistor and the fourth transistor by enabling the connection signal and the sensing signal.
